(19) United States
(12) Patent Application Publication
(10) Pub. No.: US 2024/0243071 A1
(43) Pub. Date: Jul. 18, 2024

(54) SEMICONDUCTOR DEVICE

(71) Applicant: Mitsubishi Electric Corporation, Tokyo (JP)

(72) Inventor: Shota YAMAMOTO, Tokyo (JP)

(73) Assignee: Mitsubishi Electric Corporation, Tokyo (JP)

(21) Appl. No.: 18/501,186

(22) Filed: Nov. 3, 2023

(30) Foreign Application Priority Data
Jan. 13, 2023 (JP) 2023-003806

(51) Int. Cl. H01L 23/538; H01L 25/065; H01L 25/18

(52) U.S. Cl. CPC H01L 23/5386; H01L 25/0655; H01L 25/18; H01L 24/32; H01L 2924/10253; H01L 2924/10254; H01L 2924/10272; H01L 2924/1033; H01L 2924/1067; H01L 2924/12032; H01L 2924/13055; H01L 2924/13091

(57) ABSTRACT

A semiconductor device includes a conductive pattern and a plurality of semiconductor chips. The conductive pattern is provided on an insulating substrate. The plurality of semiconductor chips is mounted on the conductive pattern. The plurality of semiconductor chips includes a first semiconductor chip and two or more second semiconductor chips electrically connected in parallel to each other. The first semiconductor chip is more likely to be affected by thermal interference than the two or more second semiconductor chips. A thickness of the conductive pattern immediately below the first semiconductor chip is larger than a thickness of the conductive pattern immediately below each of the two or more second semiconductor chips.

### BACKGROUND OF THE INVENTION

### Field of the Invention

The present disclosure relates to a semiconductor device.

### Description of the Background Art

In a technical field for improving reliability of a semiconductor device, there is proposed a technique in which heat dissipation of a semiconductor chip through which a large current flows is made better than heat dissipation of a semiconductor chip through which a small current flows (for example, Japanese Patent Application Laid-Open No. 2017-55043).

In a structure in which a plurality of identical semiconductor chips is connected in parallel to each other in order to increase the capacity of the semiconductor device, heat generated in adjacent semiconductor chips interferes. The deviation of non-uniform heat distribution generated in the semiconductor device due to the thermal interference affects the reliability of the semiconductor device.

### SUMMARY

An object of the present disclosure is to provide a semiconductor device in which reliability is improved by improving thermal non-uniformity in a plurality of semiconductor chip portions connected in parallel to each other.

A semiconductor device according to the present disclosure includes a conductive pattern and a plurality of semiconductor chips. The conductive pattern is provided on an insulating substrate. The plurality of semiconductor chips is mounted on the conductive pattern. The plurality of semiconductor chips includes a first semiconductor chip and two or more second semiconductor chips electrically connected in parallel to each other. The first semiconductor chip is more likely to be affected by thermal interference than the two or more second semiconductor chips. A thickness of the conductive pattern immediately below the first semiconductor chip is larger than a thickness of the conductive pattern immediately below each of the two or more second semiconductor chips.

Provided is the semiconductor device in which the reliability is improved by improving the thermal non-uniformity in the plurality of semiconductor chip portions connected in parallel to each other.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to a first preferred embodiment;

FIG. 2 is a cross-sectional view illustrating a configuration of the semiconductor device;

FIG. 3 is a cross-sectional view illustrating a configuration of a semiconductor device according to a second preferred embodiment;

FIG. 4 is a plan view illustrating a configuration of a semiconductor device according to a third preferred embodiment;

FIG. 5 is a cross-sectional view illustrating a configuration of the semiconductor device;

FIG. 6 is a cross-sectional view illustrating a configuration of a semiconductor device according to a modification of the third preferred embodiment;

FIG. 7 is a plan view illustrating a configuration of a semiconductor device according to a fourth preferred embodiment;

FIG. 8 is a cross-sectional view illustrating a configuration of the semiconductor device; and

FIG. 9 is a cross-sectional view illustrating a configuration of a semiconductor device according to a modification of the fourth preferred embodiment.

### DESCRIPTION OF THE PREFERRED EMBODIMENTS

### First Preferred Embodiment

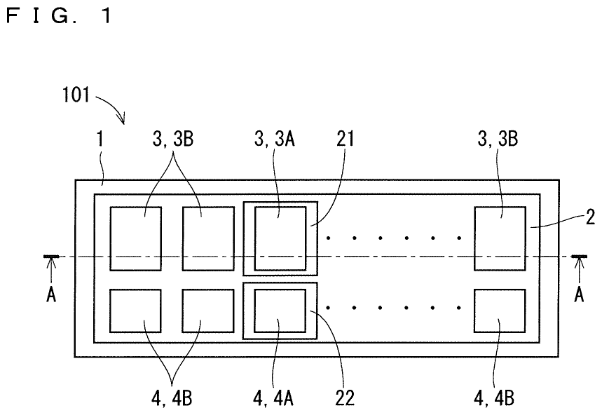

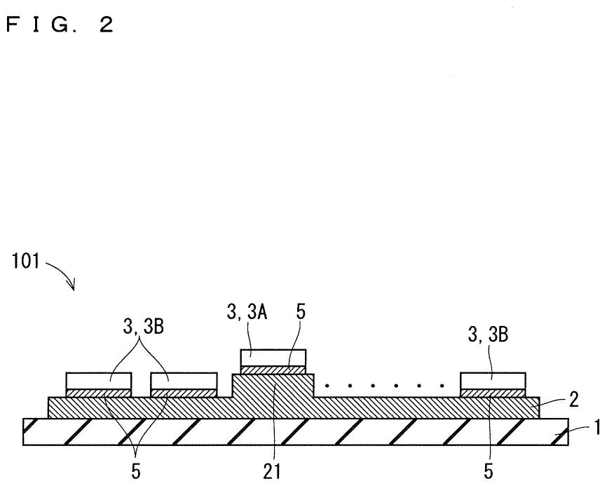

FIG. 1 is a plan view illustrating a configuration of a semiconductor device 101 according to a first preferred embodiment. The semiconductor device 101 includes an insulating substrate 1, a conductive pattern 2, a plurality of switching element chips 3, and a plurality of freewheeling element chips 4. FIG. 2 is a cross-sectional view illustrating a configuration of the semiconductor device 101. FIG. 2 illustrates a cross section taken along line A-A in FIG. 1, that is, a cross section across the plurality of switching element chips 3. Although not illustrated, a configuration of a cross section across the plurality of freewheeling element chips 4 is also the same as that in FIG. 2.

The insulating substrate 1 is made of, for example, ceramic. The insulating substrate 1 may be a substrate including a metal substrate (not illustrated) and an insulating layer (not illustrated) provided on the metal substrate. In such a case, the insulating layer is made of resin.

The conductive pattern 2 is provided on the insulating substrate 1. In a case where the insulating substrate 1 includes the above-described metal substrate and insulating layer, the conductive pattern 2 is provided on the insulating layer. The conductive pattern 2 is made of metal such as copper. The conductive pattern 2 includes patterns 21 and 22. A thickness of the conductive pattern 2 in the patterns 21 and 22 is larger than a thickness of the conductive pattern 2 in a region other than the patterns 21 and 22.

Each of the plurality of switching element chips 3 and the plurality of freewheeling element chips 4 is mounted on the conductive pattern 2 via a bonding material 5. The bonding material 5 has conductivity. The bonding material 5 is, for example, solder.

Each of the plurality of switching element chips 3 includes a switching element (not illustrated). The switching element chip 3 is a so-called power semiconductor chip. The switching element is formed using, for example, a semiconductor such as Si, or a so-called wide bandgap semiconductor such as SiC, GaN, Ga₂O₃, or diamond. The switching element is, for example, an insulated gate bipolar transistor (IGBT), but may be a metal oxide semiconductor field effect transistor (MOSFET) as well as the IGBT.

The plurality of switching element chips 3 are arranged to be aligned in a row in the lateral direction in FIG. 1. The plurality of switching element chips 3 mutually have the same structure. The plurality of switching element chips 3 are electrically connected in parallel to each other. A current uniformly flows through each of the switching elements.

The plurality of switching element chips 3 include a first switching element chip 3A and two or more second switching element chips 3B. The first switching element chip 3A is mounted on the pattern 21 of the conductive pattern 2 via the bonding material 5.

The first switching element chip 3A is placed closer to the center than the second switching element chip 3B in a region where the plurality of switching element chips 3 are arranged. Preferably, the first switching element chip 3A is placed at a central portion in the region where the plurality of switching element chips 3 are arranged. The first switching element chip 3A in the first preferred embodiment is placed between at least two second switching element chips 3B in a plan view.

In the above arrangement, the degree of thermal interference that the first switching element chip 3A receives from the adjacent or peripheral switching element chip 3 is larger than the degree of thermal interference that the second switching element chip 3B receives from the adjacent or peripheral switching element chip 3. In other words, the first switching element chip 3A is more likely to be affected by the thermal interference than the second switching element chip 3B. The degree of the influence of the thermal interference corresponds to, for example, the magnitude of a chip temperature when the plurality of switching element chips 3 are operated in a semiconductor device in which a thickness of the conductive pattern 2 is uniform. The influence of the thermal interference is large when the chip temperature is high.

A thickness of the conductive pattern 2 immediately below the first switching element chip 3A is different from a thickness of the conductive pattern 2 immediately below each of the second switching element chips 3B. In the first preferred embodiment, the thickness of the conductive pattern 2 immediately below the first switching element chip 3A is larger than a thickness of the conductive pattern 2 in the other region. For example, the thickness of the conductive pattern 2 immediately below the first switching element chip 3A is larger than the thickness of the conductive pattern 2 immediately below each of the second switching element chips 3B.

Each of the plurality of freewheeling element chips 4 includes a freewheeling diode (not illustrated). The freewheeling diode is formed using, for example, a semiconductor such as Si, or a so-called wide bandgap semiconductor such as SiC, GaN, Ga₂O₃, or diamond. The freewheeling diode is, for example, a Schottky barrier diode.

The plurality of freewheeling element chips 4 are arranged in parallel with the plurality of switching element chips 3, that is, arranged to be aligned in a row in the lateral direction in FIG. 1. The number of the freewheeling element chips 4 is the same as the number of the switching element chips 3. The freewheeling element chips 4 are arranged to have one-to-one correspondence with the switching element chips 3 in the longitudinal direction (vertical direction in FIG. 1) in a plan view. The plurality of freewheeling element chips 4 have the same structure. Each of the freewheeling diodes is electrically connected in anti-parallel to one corresponding switching element. A current uniformly flows through each of the freewheeling diodes.

The plurality of freewheeling element chips 4 include a first freewheeling element chip 4A and two or more second freewheeling element chips 4B. The first freewheeling element chip 4A is mounted on the pattern 22 of the conductive pattern 2 via the bonding material 5.

The first freewheeling element chip 4A is placed closer to the center than the second freewheeling element chip 4B in a region where the plurality of freewheeling element chips 4 are arranged. Preferably, the first freewheeling element chip 4A is placed at a central portion in the region where the plurality of freewheeling element chips 4 are arranged. The first freewheeling element chip 4A in the first preferred embodiment is placed between at least two second freewheeling element chips 4B in a plan view.

In the above arrangement, the degree of thermal interference that the first freewheeling element chip 4A receives from the adjacent or peripheral freewheeling element chip 4 is larger than the degree of thermal interference that the second freewheeling element chip 4B receives from the adjacent or peripheral freewheeling element chip 4. In other words, the first freewheeling element chip 4A is more likely to be affected by the thermal interference than the second freewheeling element chip 4B. The degree of influence of the thermal interference corresponds to, for example, the magnitude of the chip temperature when the plurality of freewheeling element chips 4 are operated in the semiconductor device 101 in which the thickness of the conductive pattern 2 is uniform. The influence of the thermal interference is large when the chip temperature is high.

A thickness of the conductive pattern 2 immediately below the first freewheeling element chip 4A is different from a thickness of the conductive pattern 2 immediately below each of the second freewheeling element chips 4B. In the first preferred embodiment, the thickness of the conductive pattern 2 immediately below the first freewheeling element chip 4A is larger than a thickness of the conductive pattern 2 in the other region. For example, the thickness of the conductive pattern 2 immediately below the first freewheeling element chip 4A is larger than the thickness of the conductive pattern 2 immediately below each of the second freewheeling element chips 4B.

In summary, the semiconductor device 101 according to the first preferred embodiment includes the conductive pattern 2 and the plurality of semiconductor chips. The semiconductor chip in the first preferred embodiment corresponds to the switching element chip 3 or the freewheeling element chip 4. The conductive pattern 2 is provided on the insulating substrate 1. The plurality of semiconductor chips is mounted on the conductive pattern 2. The plurality of semiconductor chips includes a first semiconductor chip and two or more second semiconductor chips electrically connected in parallel to each other. The first semiconductor chip in the first preferred embodiment corresponds to the first switching element chip 3A or the first freewheeling element chip 4A. Similarly, the second semiconductor chip corresponds to the second switching element chip 3B or the second freewheeling element chip 4B. The first semiconductor chip is more likely to be affected by thermal interference than the two or more second semiconductor chips. A thickness of the conductive pattern 2 immediately below the first semiconductor chip is larger than a thickness of the conductive pattern 2 immediately below each of the two or more second semiconductor chips.

The above semiconductor device 101 improves thermal non-uniformity in a plurality of semiconductor chip portions connected in parallel with each other. As a result, the reliability of the semiconductor device 101 is improved.

In the first preferred embodiment, the plurality of switching element chips 3 are electrically connected in parallel to each other, and the current uniformly flows through each of the switching elements. However, in a case where the thickness of the conductive pattern 2 in the region where the switching element chips 3 are arranged is uniform, the first switching element chip 3A arranged closer to the center than the second switching element chip 3B is more likely to be affected by the thermal interference than the second switching element chip 3B. In other words, the first switching element chip 3A is greatly affected by heat generated in the second switching element chip 3B arranged adjacent to or around the first switching element chip 3A. Therefore, a temperature of the first switching element chip 3A is likely to be higher than temperatures of the other second switching element chips 3B.

In the semiconductor device 101 of the first preferred embodiment, the thickness of the conductive pattern 2 immediately below the first switching element chip 3A is larger than the thickness of the conductive pattern 2 immediately below the second switching element chip 3B. Such a configuration alleviates the thermal interference that the first switching element chip 3A receives from the adjacent or peripheral switching element chip 3.

The semiconductor device 101 achieves efficient heat dissipation and alleviates or prevents a state where the temperature of the first switching element chip 3A becomes higher than the temperatures of the other second switching element chips 3B. Therefore, thermal non-uniformity in the plurality of switching element chips 3 is improved. The semiconductor device 101 prevents the reliability from being limited by the maximum temperature of the switching element chip.

Similarly, the plurality of freewheeling element chips 4 are electrically connected in parallel to each other, and the current uniformly flows through each of the freewheeling diodes. In a case where the thickness of the conductive pattern 2 in the region where the freewheeling element chips 4 are arranged is uniform, the first freewheeling element chip 4A arranged closer to the center than the second freewheeling element chip 4B is more likely to be affected by the thermal interference than the second freewheeling element chip 4B. In other words, the first freewheeling element chip 4A is greatly affected by heat generated in the second freewheeling element chip 4B arranged adjacent to or around the first freewheeling element chip 4A. Therefore, a temperature of the first freewheeling element chip 4A is likely to be higher than temperatures of the other second freewheeling element chips 4B.

In the semiconductor device 101 of the first preferred embodiment, the thickness of the conductive pattern 2 immediately below the first freewheeling element chip 4A is larger than the thickness of the conductive pattern 2 immediately below the second freewheeling element chip 4B. Such a configuration alleviates the thermal interference that the first freewheeling element chip 4A receives from the freewheeling element chip 4 adjacent to or around the first freewheeling element chip 4A.

The semiconductor device 101 achieves efficient heat dissipation and alleviates or prevents a state where the temperature of the first freewheeling element chip 4A becomes higher than the temperatures of the other second freewheeling element chips 4B. Therefore, thermal non-uniformity in the freewheeling element chips 4 is improved. The semiconductor device 101 prevents the reliability from being limited by the maximum temperature of the freewheeling element chip.

Each of the switching element chips 3 and each of the freewheeling element chips 4 may be one chip integrated with each other. In such a case, the switching element is a reverse-conducting IGBT (RC-IGBT) in which an IGBT and a Schottky barrier diode are formed in one semiconductor substrate.

### Second Preferred Embodiment

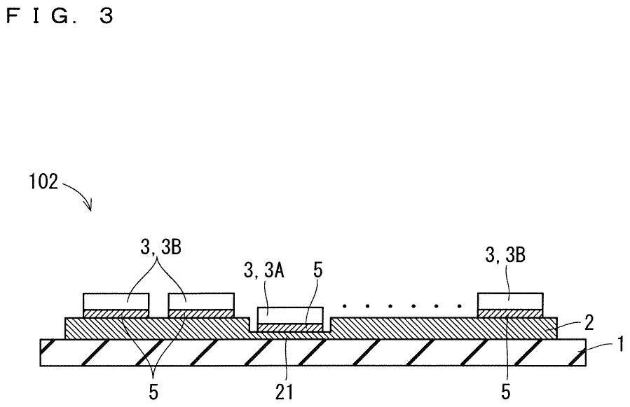

FIG. 3 is a cross-sectional view illustrating a configuration of a semiconductor device 102 according to a second preferred embodiment. Similarly to FIG. 2, FIG. 3 illustrates A-A cross section across the plurality of switching element chips 3 in FIG. 1. Configurations of the insulating substrate 1, the plurality of switching element chips 3, and the plurality of freewheeling element chips 4 (not illustrated in FIG. 3) in the semiconductor device 102 are the same as those in the first preferred embodiment. In addition, a configuration of a cross section across the plurality of freewheeling element chips 4 is similar to that in FIG. 3. On the other hand, a configuration of the conductive pattern 2 in the second preferred embodiment is different from the configuration of the conductive pattern 2 in the first preferred embodiment.

A thickness of the conductive pattern 2 in the patterns 21 and 22 is smaller than a thickness of the conductive pattern 2 in a region other than the patterns 21 and 22.

A thickness of the conductive pattern 2 immediately below the first switching element chip 3A is smaller than a thickness of the conductive pattern 2 in the other region. For example, the thickness of the conductive pattern 2 immediately below the first switching element chip 3A is smaller than a thickness of the conductive pattern 2 immediately below each of the second switching element chips 3B.

A thickness of the conductive pattern 2 immediately below the first freewheeling element chip 4A is smaller than a thickness of the conductive pattern 2 in the other region. For example, the thickness of the conductive pattern 2 immediately below the first freewheeling element chip 4A is smaller than a thickness of the conductive pattern 2 immediately below each of the second freewheeling element chips 4B.

According to such a configuration, thermal resistance of the conductive pattern 2 immediately below the first switching element chip 3A decreases. The semiconductor device 102 alleviates or prevents a state where a temperature of the first switching element chip 3A becomes higher than temperatures of the other second switching element chips 3B. Therefore, the thermal non-uniformity in the plurality of switching element chips 3 is improved, and the reliability of the semiconductor device 102 is improved.

In addition, thermal resistance of the conductive pattern 2 immediately below the first freewheeling element chip 4A decreases. The semiconductor device 102 alleviates or prevents a state where a temperature of the first freewheeling element chip 4A becomes higher than temperatures of the other second freewheeling element chips 4B. Therefore, the thermal non-uniformity in the plurality of freewheeling element chips 4 is improved, and the reliability of the semiconductor device 102 is improved.

### Third Preferred Embodiment

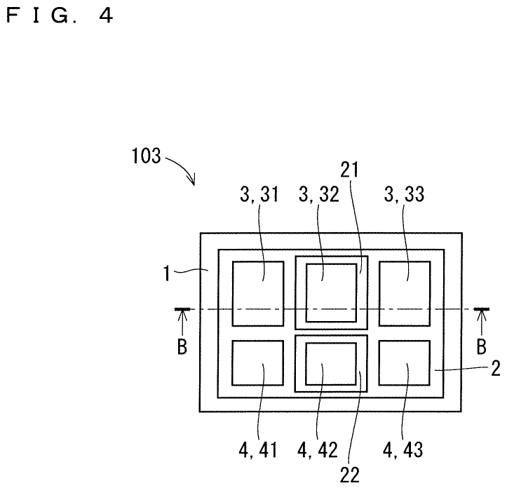

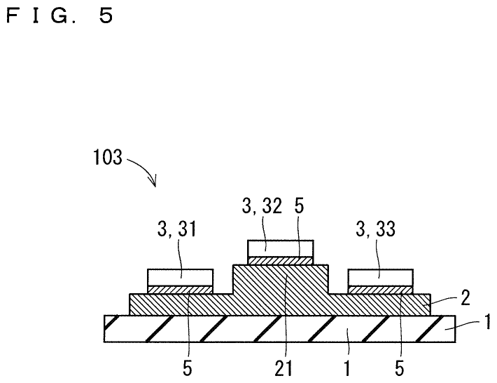

FIG. 4 is a plan view illustrating a configuration of a semiconductor device 103 according to a third preferred embodiment. The semiconductor device 103 includes the insulating substrate 1, the conductive pattern 2, three switching element chips 3, and three freewheeling element chips 4. FIG. 5 is a cross-sectional view illustrating a configuration of the semiconductor device 103. FIG. 5 illustrates a cross section taken along line B-B in FIG. 4, that is, a cross section across the three switching element chips 3. Although not illustrated, a configuration of a cross section across the three freewheeling element chips 4 is similar to that in FIG. 5.

The three switching element chips 3 are one form of the plurality of switching element chips 3 illustrated in the first preferred embodiment. The three freewheeling element chips 4 are one form of the plurality of freewheeling element chips 4 illustrated in the first preferred embodiment.

A thickness of the conductive pattern 2 in the patterns 21 and 22 is larger than a thickness of the conductive pattern 2 in a region other than the patterns 21 and 22.

Each of the three switching element chips 3 includes a switching element (not illustrated). The three switching element chips 3 are arranged side by side in the lateral direction in order from an end. The three switching element chips 3 are electrically connected in parallel to each other. The three switching element chips 3 have the same structure. A current uniformly flows through each of the switching elements.

The three switching element chips 3 include a first switching element chip 32 and two second switching element chips 31 and 33. The first switching element chip 32 is mounted on the pattern 21 of the conductive pattern 2 via the bonding material 5.

The first switching element chip 32 is placed between the two second switching element chips 31 and 33 in a plan view. Among the three switching element chips 3, the first switching element chip 32 arranged at a central portion is most susceptible to thermal interference.

A thickness of the conductive pattern 2 immediately below the first switching element chip 32 is larger than a thickness of the conductive pattern 2 immediately below each of the two second switching element chips 31 and 33. For example, only the thickness of the conductive pattern 2 immediately below the first switching element chip 32 may be larger than a thickness of the conductive patterns 2 in the other region.

Each of the three freewheeling element chips 4 includes a freewheeling diode (not illustrated). The three freewheeling element chips 4 are arranged in parallel with the three switching element chips 3, that is, arranged side by side in the lateral direction in order from an end. The three freewheeling element chips 4 have the same structure. Each of the freewheeling diodes is electrically connected in anti-parallel to one adjacent switching element. A current uniformly flows through each of the freewheeling diodes.

The three freewheeling element chips 4 include a first freewheeling element chip 42 and two second freewheeling element chips 41 and 43. The first freewheeling element chip 42 is mounted on the pattern 22 of the conductive pattern 2 via the bonding material 5.

The first freewheeling element chip 42 is placed between the two second freewheeling element chips 41 and 43 in a plan view. The three freewheeling element chips 4 are arranged to have one-to-one correspondence with the three switching element chips 3 in the longitudinal direction (vertical direction) in a plan view. For example, the first freewheeling element chip 42 is placed vertically side by side with the first switching element chip 32. The two second freewheeling element chips 41 and 43 are arranged vertically side by side with the two second switching element chips 31 and 33, respectively. Among the three freewheeling element chips 4, the first freewheeling element chip 42 arranged at a central portion is most susceptible to thermal interference.

A thickness of the conductive pattern 2 immediately below the first freewheeling element chip 42 is larger than a thickness of the conductive pattern 2 immediately below each of the two second freewheeling element chips 41 and 43. For example, only the thickness of the conductive pattern 2 immediately below the first freewheeling element chip 42 may be larger than a thickness of the conductive pattern 2 in the other region.

According to the semiconductor device 103 of the third preferred embodiment, effects similar to those of the first preferred embodiment can be obtained. In three-parallel configuration, among the switching element chip 3 and the freewheeling element chip 4, the first switching element chip 32 and the first freewheeling element chip 42 arranged at the central portion are most susceptible to thermal interference. Chip temperatures of the first switching element chip 32 and the first freewheeling element chip 42 are likely to be higher than the other chip temperatures. Since the thickness of the conductive pattern 2 immediately below the first switching element chip 32 and the first freewheeling element chip 42 at the central portion is thick in the semiconductor device 103, thermal non-uniformity in the switching element chips 3 and thermal non-uniformity in the freewheeling element chips 4 can be suppressed.

### Modification of Third Preferred Embodiment

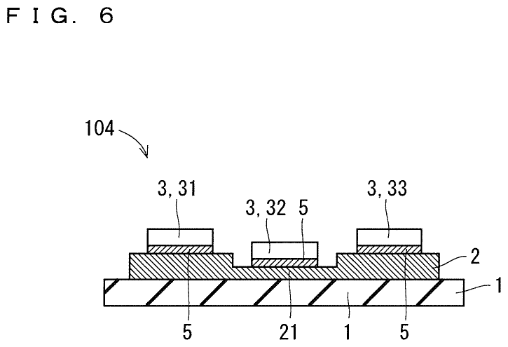

FIG. 6 is a cross-sectional view illustrating a configuration of a semiconductor device 104 according to a modification of the third preferred embodiment. Similarly to FIG. 5, FIG. 6 illustrates B-B cross section across the three switching element chips 3 in FIG. 4. Configurations of the insulating substrate 1, the three switching element chips 3, and the three freewheeling element chips 4 (not illustrated in FIG. 6) in the semiconductor device 104 are the same as those in the third preferred embodiment. In addition, a configuration of a cross section across the three freewheeling element chips 4 is similar to that in FIG. 6. On the other hand, a configuration of the conductive pattern 2 in the modification of the third preferred embodiment is different from the configuration of the conductive pattern 2 in the third preferred embodiment.

A thickness of the conductive pattern 2 in the patterns 21 and 22 is smaller than a thickness of the conductive pattern 2 in a region other than the patterns 21 and 22.

A thickness of the conductive pattern 2 immediately below the first switching element chip 32 is smaller than a thickness of the conductive pattern 2 immediately below each of the two second switching element chips 31 and 33. For example, only the thickness of the conductive pattern 2 immediately below the first switching element chip 32 may be smaller than a thickness of the conductive patterns 2 in the other region.

A thickness of the conductive pattern 2 immediately below the first freewheeling element chip 42 is smaller than a thickness of the conductive pattern 2 immediately below each of the two second freewheeling element chips 41 and 43. For example, only the thickness of the conductive pattern 2 immediately below the first freewheeling element chip 42 may be smaller than a thickness of the conductive pattern 2 in the other region.

According to the semiconductor device 104 of the modification of the third preferred embodiment, effects similar to those of the second preferred embodiment can be obtained. Since the thickness of the conductive pattern 2 immediately below the first switching element chip 32 and the first freewheeling element chip 42 at the central portion is thin in the semiconductor device 104, thermal non-uniformity in the switching element chips 3 and thermal non-uniformity in the freewheeling element chips 4 can be suppressed.

As described in the third preferred embodiment and its modification, the chip temperatures of the first switching element chip 32 and the first freewheeling element chip 42 are prevented from being higher than the other chip temperatures by adjusting (that is, thickening or thinning) the thickness of the conductive pattern 2 immediately below the first switching element chip 32 and the first freewheeling element chip 42 at the central portion.

### Fourth Preferred Embodiment

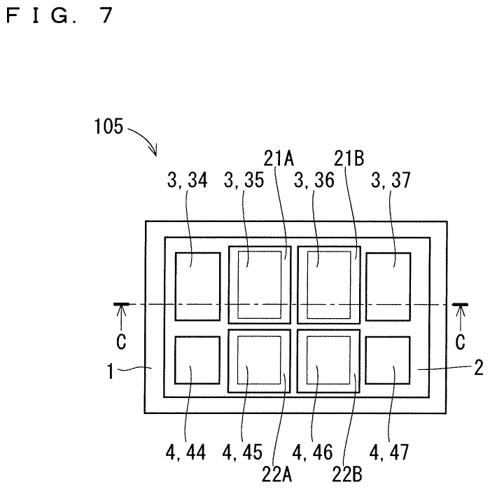

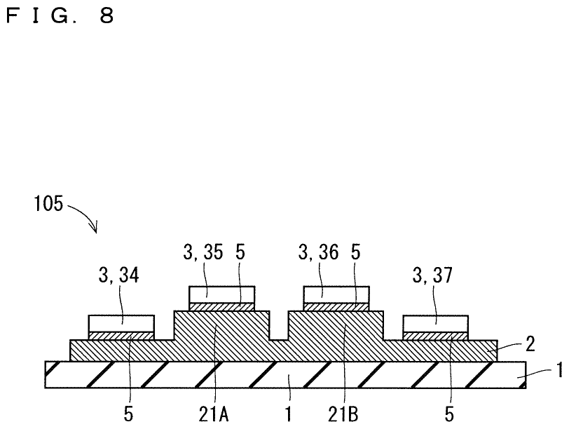

FIG. 7 is a plan view illustrating a configuration of a semiconductor device 105 according to a fourth preferred embodiment. The semiconductor device 105 includes the insulating substrate 1, the conductive pattern 2, four switching element chips 3, and four freewheeling element chips 4. FIG. 8 is a cross-sectional view illustrating a configuration of the semiconductor device 105. FIG. 8 illustrates a cross section taken along line C-C in FIG. 7, that is, a cross section across the four switching element chips 3. Although not illustrated, a configuration of a cross section across the four freewheeling element chips 4 is similar to that in FIG. 8.

The four switching element chips 3 are one form of the plurality of switching element chips 3 illustrated in the first preferred embodiment. The four freewheeling element chips 4 are one form of the plurality of freewheeling element chips 4 illustrated in the first preferred embodiment.

The conductive pattern 2 includes patterns 21A, 21B, 22A, and 22B. A thickness of the conductive pattern 2 in the patterns 21A, 21B, 22A, and 22B is larger than a thickness of the conductive pattern 2 in the other region.

Each of the four switching element chips 3 includes a switching element (not illustrated). The four switching element chips 3 are arranged side by side in the lateral direction in order from an end. The four switching element chips 3 are electrically connected in parallel to each other. The four switching element chips 3 have the same structure. A current uniformly flows through each of the switching elements.

The four switching element chips 3 include two first switching element chips 35 and 36 and two second switching element chips 34 and 37. The first switching element chips 35 and 36 are mounted on the patterns 21A and 21B of the conductive pattern 2 via the bonding material 5.

The two first switching element chips 35 and 36 are arranged between the two second switching element chips 34 and 37 in a plan view. Among the four switching element chips 3, the two first switching element chips 35 and 36 arranged at a central portion are most susceptible to thermal interference.

A thickness of the conductive pattern 2 immediately below each of the first switching element chips 35 and 36 is larger than a thickness of the conductive pattern 2 immediately below each of the second switching element chips 34 and 37. For example, only the thickness of the conductive pattern 2 immediately below each of the two first switching element chips 35 and 36 may be larger than the thickness of the conductive pattern 2 in the other region.

Each of the four freewheeling element chips 4 includes a freewheeling diode (not illustrated). The four freewheeling element chips 4 are arranged in parallel with the four switching element chips 3, that is, arranged side by side in the lateral direction in order from an end. The four freewheeling element chips 4 have the same structure. Each of the freewheeling diodes is electrically connected in anti-parallel to one adjacent switching element. A current uniformly flows through each of the freewheeling diodes.

The four freewheeling element chips 4 include two first freewheeling element chips 45 and 46 and two second freewheeling element chips 44 and 47. The first freewheeling element chips 45 and 46 are mounted on the patterns 22A and 22B of the conductive pattern 2 via the bonding material 5.

The two first freewheeling element chips 45 and 46 are arranged between the two second freewheeling element chips 44 and 47 in a plan view. The four freewheeling element chips 4 are arranged to have one-to-one correspondence with the four switching element chips 3 in the longitudinal direction (vertical direction) in a plan view. For example, the two first freewheeling element chips 45 and 46 are arranged side by side vertically with the two first switching element chips 35 and 36, respectively. The two second freewheeling element chips 44 and 47 are arranged vertically side by side with the two second switching element chips 34 and 37, respectively. Among the four freewheeling element chips 4, the two first freewheeling element chips 45 and 46 arranged at a central portion are most susceptible to thermal interference.

A thickness of the conductive pattern 2 immediately below each of the two first freewheeling element chips 45 and 46 is larger than a thickness of the conductive pattern 2 immediately below each of the two second freewheeling element chips 44 and 47. For example, only the thickness of the conductive pattern 2 immediately below each of the two first freewheeling element chips 45 and 46 may be larger than the thickness of the conductive pattern 2 in the other region.

According to the semiconductor device 105 of the fourth preferred embodiment, effects similar to those of the first preferred embodiment can be obtained. In four-parallel configuration, among the switching element chip 3 and the freewheeling element chip 4, the first switching element chips 35 and 36 and the first freewheeling element chips 45 and 46 arranged at the central portion are most susceptible to thermal interference. Chip temperatures of the first switching element chips 35 and 36 and the first freewheeling element chips 45 and 46 are likely to be higher than the other chip temperatures. Since the thickness of the conductive pattern 2 immediately below the first switching element chips 35 and 36 and the first freewheeling elements chip 45 and 46 at the central portion is thick in the semiconductor device 105, thermal non-uniformity in the switching element chips 3 and thermal non-uniformity in the freewheeling element chips 4 can be suppressed.

### Modification of Fourth Preferred Embodiment

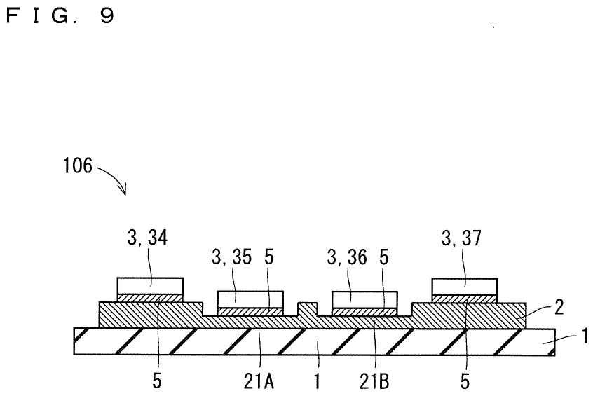

FIG. 9 is a cross-sectional view illustrating a configuration of a semiconductor device 106 according to a modification of the fourth preferred embodiment. Similarly to FIG. 8, FIG. 9 illustrates C-C cross section across the four switching element chips 3 in FIG. 7. Configurations of the insulating substrate 1, the four switching element chips 3, and the four freewheeling element chips 4 (not illustrated in FIG. 9) in the semiconductor device 106 are the same as those in the fourth preferred embodiment. In addition, a configuration of a cross section across the four freewheeling element chips 4 is similar to that in FIG. 9. On the other hand, a configuration of the conductive pattern 2 in the modification of the fourth preferred embodiment is different from the configuration of the conductive pattern 2 in the fourth preferred embodiment.

A thickness of the conductive pattern 2 in the patterns 21A, 21B, 22A, and 22B is smaller than a thickness of the conductive pattern 2 in the other region.

A thickness of the conductive pattern 2 immediately below each of the two first switching element chips 35 and 36 is smaller than a thickness of the conductive pattern 2 immediately below each of the two second switching element chips 34 and 37. For example, only the thickness of the conductive pattern 2 immediately below each of the two first switching element chips 35 and 36 may be smaller than the thickness of the conductive pattern 2 in the other region.

A thickness of the conductive pattern 2 immediately below each of the two first freewheeling element chips 45 and 46 is smaller than a thickness of the conductive pattern 2 immediately below each of the two second freewheeling element chips 44 and 47. For example, only the thickness of the conductive pattern 2 immediately below each of the two first freewheeling element chips 45 and 46 may be smaller than the thickness of the conductive pattern 2 in the other region.

According to the semiconductor device 106 of the modification of the fourth preferred embodiment, effects similar to those of the second preferred embodiment can be obtained. Since the thickness of the conductive pattern 2 immediately below the first switching element chips 35 and 36 and the first freewheeling elements chip 45 and 46 at the central portion is thin in the semiconductor device 106, thermal non-uniformity in the switching element chips 3 and thermal non-uniformity in the freewheeling element chips 4 can be suppressed.

As described in the fourth preferred embodiment and its modification, the chip temperatures of the first switching element chips 35 and 36 and the first freewheeling element chips 45 and 46 are prevented from being higher than the other chip temperatures by adjusting (that is, thickening or thinning) the thickness of the conductive pattern 2 immediately below the first switching element chips 35 and 36 and the first freewheeling element chips 45 and 46 at the central portion.

In the present disclosure, each of the preferred embodiments can be freely combined, and each of the preferred embodiments can be appropriately modified or omitted.

Hereinafter, various aspects of the present disclosure will be collectively described as appendices.

### (Appendix 1)

A semiconductor device comprising:
a conductive pattern provided on an insulating substrate; and
a plurality of semiconductor chips that is mounted on the conductive pattern and electrically connected in parallel to each other and that includes a first semiconductor chip and two or more second semiconductor chips,
wherein the first semiconductor chip is more likely to be affected by thermal interference than the two or more second semiconductor chips, and
a thickness of the conductive pattern immediately below the first semiconductor chip is larger than a thickness of the conductive pattern immediately below each of the two or more second semiconductor chips.

### (Appendix 2)

A semiconductor device comprising:
a conductive pattern provided on an insulating substrate; and
a plurality of semiconductor chips that is mounted on the conductive pattern and electrically connected in parallel to each other and that includes a first semiconductor chip and two or more second semiconductor chips,
wherein the first semiconductor chip is more likely to be affected by thermal interference than the two or more second semiconductor chips, and
a thickness of the conductive pattern immediately below the first semiconductor chip is smaller than a thickness of the conductive pattern immediately below each of the two or more second semiconductor chips.

### (Appendix 3)

A semiconductor device comprising:
a conductive pattern provided on an insulating substrate; and
a plurality of semiconductor chips that is mounted on the conductive pattern and electrically connected in parallel to each other and that includes a first semiconductor chip and two or more second semiconductor chips,
wherein the first semiconductor chip is placed between the two or more second semiconductor chips in a plan view, and
a thickness of the conductive pattern immediately below the first semiconductor chip is different from a thickness of the conductive pattern immediately below each of the two or more second semiconductor chips.

### (Appendix 4)

The semiconductor device according to any one of Appendices 1 to 3, wherein each of the plurality of semiconductor chips connected in parallel is a power semiconductor chip including a switching element.

### (Appendix 5)

The semiconductor device according to any one of Appendices 1 to 4, wherein the plurality of semiconductor chips connected in parallel includes three semiconductor chips including the first semiconductor chip and a pair of the second semiconductor chips.

### (Appendix 6)

The semiconductor device according to any one of Appendices 1 to 4, wherein the plurality of semiconductor chips connected in parallel includes four semiconductor chips including a pair of the first semiconductor chips and a pair of the second semiconductor chips.

### (Appendix 7)

The semiconductor device according to any one of Appendices 1 to 6, wherein each semiconductor chip in the plurality of semiconductor chips connected in parallel has an identical structure.

While the disclosure has been shown and described in detail, the foregoing description is in all aspects illustrative and not restrictive. It is therefore understood that numerous modifications and variations can be devised.

What is claimed is:

1. A semiconductor device comprising:
a conductive pattern provided on an insulating substrate; and
a plurality of semiconductor chips that is mounted on the conductive pattern and electrically connected in parallel to each other and that includes a first semiconductor chip and two or more second semiconductor chips,
wherein
the first semiconductor chip is more likely to be affected by thermal interference than the two or more second semiconductor chips, and
a thickness of the conductive pattern immediately below the first semiconductor chip is larger than a thickness of the conductive pattern immediately below each of the two or more second semiconductor chips.

2. A semiconductor device comprising:
a conductive pattern provided on an insulating substrate; and
a plurality of semiconductor chips that is mounted on the conductive pattern and electrically connected in parallel to each other and that includes a first semiconductor chip and two or more second semiconductor chips,
wherein
the first semiconductor chip is more likely to be affected by thermal interference than the two or more second semiconductor chips, and
a thickness of the conductive pattern immediately below the first semiconductor chip is smaller than a thickness of the conductive pattern immediately below each of the two or more second semiconductor chips.

3. A semiconductor device comprising:
a conductive pattern provided on an insulating substrate; and
a plurality of semiconductor chips that is mounted on the conductive pattern and electrically connected in parallel to each other and that includes a first semiconductor chip and two or more second semiconductor chips,
wherein
the first semiconductor chip is placed between the two or more second semiconductor chips in a plan view, and
a thickness of the conductive pattern immediately below the first semiconductor chip is different from a thickness of the conductive pattern immediately below each of the two or more second semiconductor chips.

4. The semiconductor device according to claim 1, wherein each of the plurality of semiconductor chips connected in parallel is a power semiconductor chip including a switching element.

5. The semiconductor device according to claim 2, wherein each of the plurality of semiconductor chips connected in parallel is a power semiconductor chip including a switching element.

6. The semiconductor device according to claim 3, wherein each of the plurality of semiconductor chips connected in parallel is a power semiconductor chip including a switching element.

7. The semiconductor device according to claim 1, wherein the plurality of semiconductor chips connected in parallel includes three semiconductor chips including the first semiconductor chip and a pair of the second semiconductor chips.

8. The semiconductor device according to claim 2, wherein the plurality of semiconductor chips connected in parallel includes three semiconductor chips including the first semiconductor chip and a pair of the second semiconductor chips.

9. The semiconductor device according to claim 3, wherein the plurality of semiconductor chips connected in parallel includes three semiconductor chips including the first semiconductor chip and a pair of the second semiconductor chips.

10. The semiconductor device according to claim 4, wherein the plurality of semiconductor chips connected in parallel includes three semiconductor chips including the first semiconductor chip and a pair of the second semiconductor chips.

11. The semiconductor device according to claim 1, wherein the plurality of semiconductor chips connected in parallel includes four semiconductor chips including a pair of the first semiconductor chips and a pair of the second semiconductor chips.

12. The semiconductor device according to claim 2, wherein the plurality of semiconductor chips connected in parallel includes four semiconductor chips including a pair of the first semiconductor chips and a pair of the second semiconductor chips.

13. The semiconductor device according to claim 3, wherein the plurality of semiconductor chips connected in parallel includes four semiconductor chips including a pair of the first semiconductor chips and a pair of the second semiconductor chips.

14. The semiconductor device according to claim 4, wherein the plurality of semiconductor chips connected in parallel includes four semiconductor chips including a pair of the first semiconductor chips and a pair of the second semiconductor chips.

15. The semiconductor device according to claim 1, wherein each semiconductor chip in the plurality of semiconductor chips connected in parallel has an identical structure.

16. The semiconductor device according to claim 2, wherein each semiconductor chip in the plurality of semiconductor chips connected in parallel has an identical structure.

17. The semiconductor device according to claim 3, wherein each semiconductor chip in the plurality of semiconductor chips connected in parallel has an identical structure.

18. The semiconductor device according to claim 4, wherein each semiconductor chip in the plurality of semiconductor chips connected in parallel has an identical structure.

19. The semiconductor device according to claim 7, wherein each semiconductor chip in the plurality of semiconductor chips connected in parallel has an identical structure.

20. The semiconductor device according to claim 11, wherein each semiconductor chip in the plurality of semiconductor chips connected in parallel has an identical structure.
